(19) United States
(12) Patent Application Publication
(10) Pub. No.: US 2021/0258697 A1
(43) Pub. Date: Aug. 19, 2021

(54) Layered Ferroelectric Sc(x)Al(1-x)N Transducer

(71) Applicants: University of Florida Research Foundation, Incorporated, Gainesville, FL (US); OEM Group, LLC, Gilbert, AZ (US)

(72) Inventors: Roozbeh Tabrizian, Gainesville, FL (US); Farid S. Alokozai, Scottsdale, AZ (US)

(21) Appl. No.: 17/170,138

(22) Filed: Feb. 8, 2021

Related U.S. Application Data
(60) Provisional application No. 62/976,812, filed on Feb. 14, 2020.

(51) Int. Cl. H04R 17/00; H01L 27/20; B06B 1/06

(52) U.S. Cl. CPC H04R 17/00; B06B 1/0681; H01L 27/20

(57) ABSTRACT

A ferroelectric transducer includes, in part, a first electrode positioned above a substrate; a composite stack positioned above the first electrode, and a second electrode positioned above the composite stack. The composite stack may include one or more alternate layers of a ferroelectric layer and a transition-metal nitride layer. The transition-metal nitride layer can be positioned above a corresponding ferroelectric layer, except the topmost ferroelectric layer in the composite stack. The ferroelectric layer comprises a scandium-doped aluminum nitride (ScₓAl₁₋ₓN) film, wherein 0<x<1.

### CROSS-REFERENCE TO RELATED APPLICATIONS

This patent application claims priority to Provisional Application Ser. No. 62/976,812, filed Feb. 14, 2020, which is incorporated herein by reference in its entirety.

### TECHNICAL FIELD

The present application relates to the technical field of electric transducers. Particularly, it is related to a ferroelectric switching device.

### BACKGROUND

A ferroelectric switching behavior in Scandium-Doped Aluminum Nitride (ScₓAl₁₋ₓN) films has been demonstrated recently. This behavior occurs in ScₓAl₁₋ₓN films where the ScₓAl₁₋ₓN films have a high Scandium (Sc) content (i.e. x>27%), where x is the concentration of scandium and 1−x is the concentration of aluminum (Al). The ScₓAl₁₋ₓN films illustrate a very large electromechanical coupling which only increases with Sc content (up to x<45%). This characterization suggests the potential for realization of a new class of intrinsically tunable acoustic spectral processors for reconfigurable RF front-end (RFFE) applications.

However, several major challenges exist toward realization of such potential: (a) large DC voltages are required to overcome a very large coercive field existing in the ScₓAl₁₋ₓN films in order to switch the film's polarization, and such large DC voltages may not be readily available on a standard integrated circuit chip; (b) the acoustic resonator's quality factor (Q) of the ScₓAl₁₋ₓN films will be reduced significantly with increasing Sc content; and (c) applying reactive ion etching (RIE) on ScₓAl₁₋ₓN films in a patterning process meets severe challenge with increased Sc content, preventing properly patterning of ScₓAl₁₋ₓN films in fabricating an in-plane or contour-mode ScₓAl₁₋ₓN resonator.

Based on the foregoing, a need exists for an improved ferroelectric transducer made of ScₓAl₁₋ₓN films.

### BRIEF SUMMARY

A ferroelectric Scandium-Doped Aluminum Nitride (ScₓAl₁₋ₓN) transducer is disclosed which does not require excessive scandium doping concentration and has demonstrated ferroelectric switching at low voltages available on integrated circuit chips. By depositing successively layered ScₓAl₁₋ₓN and ultra-thin transition-metal nitrides films, lateral mechanical stress is mediated in the film stack. The required energy to surpass the transition barrier from hexagonal to layered-hexagonal morphology is accommodated through the extra lateral mechanical stress. As a result, ferroelectric behavior in the transducer is enhanced.

In some embodiments, the ferroelectric transducer comprises a substrate, a first electrode, a composite stack, and a second electrode.

In some embodiments, the first electrode is positioned above the substrate. The substrate may comprise a silicon layer. In some embodiments, the substrate comprises a Bragg mirror on single crystal silicon layer. The first electrode may act as a bottom electrode.

In some embodiments, the composite stack is positioned above the first electrode. The composite stack comprises one or more alternate layers of a ferroelectric layer and a transition-metal nitride layer. In some embodiments, the transition-metal nitride layer is positioned above a corresponding ferroelectric layer except the topmost ferroelectric layer in the composite stack. In some embodiments, the ferroelectric layer comprises an aluminum scandium nitride layer (ScₓAl₁₋ₓN), in which 0<x<1. The Al₁₋ₓScₓN becomes ferroelectric when scandium content exceeds 27%. In some embodiments, the ferroelectric layer comprises aluminum-scandium-nitride films (ScₓAl₁₋ₓN) where x is at least 0.27. In some embodiments, the ferroelectric layer comprises aluminum-scandium-nitride films (ScₓAl₁₋ₓN) where 0.27<x<0.45. In some embodiments, the ferroelectric layer has a thickness of about 10 nanometers to about 100 nanometers. In some embodiments, the transition-metal nitride comprises titanium nitride (TiN). Alternatively, in some embodiments, the transition-metal nitride comprises tantalum nitride (TaN). Further, in some embodiments, the transition-metal nitride layer has a thickness of about 5 nanometers to about 20 nanometers.

In some embodiments, the second electrode is positioned above the composite stack. The second electrode may act as a top electrode.

In some embodiments, each of the transition-metal nitride layers is coupled to an external switching voltage for switching a polarization of a corresponding ScₓAl₁₋ₓN layer, the external switching voltage of each transition-metal nitride layer is independently controlled from each other, and the plurality of ScₓAl₁₋ₓN films each is configured to have a room for connecting to the external switching voltage.

In some embodiments, the first and second electrodes comprise one of molybdenum (MO), platinum (Pt), gold (Au), silver (Ag), copper (Cu), or aluminum (Al), etc.

In some embodiments, the plurality of ScₓAl₁₋ₓN films is configured to have a thickness in the range of a few nanometers (nm) to hundreds of nanometers.

In some embodiments, the plurality of ScₓAl₁₋ₓN films each is configured to be equal to or thinner than another film in the plurality of ScₓAl₁₋ₓN films below said film.

Some embodiments disclose a method of fabricating the ferroelectric transducer. In some embodiments, the method comprises forming a first electrode above a substrate, forming a composite stack above the first electrode, and forming a second electrode above the composite stack.

In some embodiments, forming the composite stack comprises forming one or more alternate layers of a ferroelectric layer and a transition-metal nitride layer. In some embodiments, the ferroelectric layer comprises a scandium-doped aluminum nitride layer (ScₓAl₁₋ₓN), wherein 0<x<1. In some embodiments, the transition-metal nitride layer is positioned above a corresponding ferroelectric layer except the topmost ferroelectric layer in the composite stack.

In some embodiments, the plurality of ScₓAl₁₋ₓN films and the transition metal nitride layers are formed by applying one of the film deposition techniques including molecular beam epitaxy (MBE), atomic layer deposition (ALD), reactive magnetron sputtering, or physical vapor deposition (PVD). In some embodiments, the deposition is followed by applying rapid thermal annealing (RTA) to the film stack at a predetermined temperature. The temperature meets requirements not to damage the ferroelectric transducer.

In some embodiments, a seed layer is grown before depositing each of the plurality of ScₓAl₁₋ₓN films for better adhesion. In some embodiments, the seed layer comprises aluminum nitride (AlN) or any other metal nitride.

In some embodiments, the transition-metal nitride layer comprises TiN or TaN.

In some embodiments, the first and second electrodes serve as the ground and excitation electrodes respectively.

### BRIEF DESCRIPTION OF DRAWINGS

The accompanying figures, in which like reference numerals refer to identical or functionally-similar elements throughout the separate views and which are incorporated in and form a part of the specification, further illustrate the embodiments and, together with the detailed description, serve to explain the embodiments disclosed.

FIG. 1a shows a perspective view of a ScₓAl₁₋ₓN ferroelectric transducer, in accordance with some embodiments of the present invention;

FIG. 1b illustrates a schematic cross-sectional view of an exemplary ScₓAl₁₋ₓN ferroelectric transducer, in accordance with some embodiments;

FIG. 2a shows a cross-sectional image from a transmission electron microscopy (XTEM) measurement of a stress-mediated Sc_{0.32}Al_{0.68}N—TiN transducer sample, in accordance with some embodiments;

FIGS. 2b and 2c show the X-ray diffraction (XRD) data across the Sc_{0.32}Al_{0.68}N peak and across the TiN peak, respectively from the fabricated sample in FIG. 2a;

FIG. 3a demonstrates the cross-sectional image from a XTEM measurement of the transducer stack of Sc_{0.32}Al_{0.68}N films, in accordance with some embodiments; and

FIG. 3b shows measured loops of polarization versus electric field (P-E) of different Sc_{0.32}Al_{0.68}N film layers with different thickness within the transducer stack after rapid thermal annealing (RTA), in accordance with some embodiments.

### DETAILED DESCRIPTION

It should be understood at the outset that although illustrative implementations of one or more embodiments are illustrated below, the disclosed systems and methods may be implemented using any number of techniques, whether currently known or not yet in existence. The disclosure should in no way be limited to the illustrative implementations, drawings, and techniques illustrated below, but may be modified within the scope of the appended claims along with their full scope of equivalents. The following brief definition of terms shall apply throughout the application:

The term “comprising” means including but not limited to and should be interpreted in the manner it is typically used in the patent context. The phrases “in one embodiment,” “according to one embodiment,” and the like generally mean that the particular feature, structure, or characteristic following the phrase may be included in at least one embodiment of the present invention, and may be included in more than one embodiment of the present invention (importantly, such phrases do not necessarily refer to the same embodiment). If the specification describes something as “exemplary” or an “example,” it should be understood that refers to a non-exclusive example; The terms “about” or “approximately” or the like, when used with a number, may mean that specific number, or alternatively, a range in proximity to the specific number, as understood by persons of skill in the art field.

If the specification states a component or feature “may,” “can,” “could,” “should,” “would,” “preferably,” “possibly,” “typically,” “optionally,” “for example,” “often,” or “might” (or other such language) be included or have a characteristic, that particular component or feature is not required to be included or to have the characteristic. Such component or feature may be optionally included in some embodiments, or it may be excluded.

Such alterations, modifications, and improvements are intended to be part of this disclosure and are intended to be within the spirit and scope of the invention. Further, though advantages of the present invention are indicated, it should be appreciated that not every embodiment of the invention will include every described advantage. Some embodiments may not implement any features described as advantageous herein and in some instances. Accordingly, the foregoing description and drawings are by way of example only.

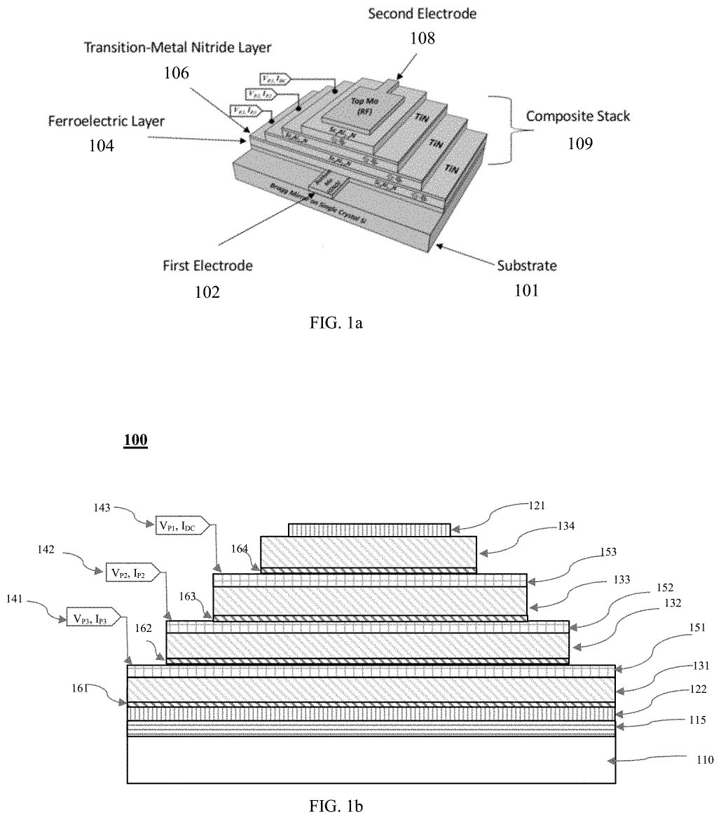

FIG. 1a shows a perspective view of a Scandium-doped Aluminum Nitride (ScₓAl₁₋ₓN) ferroelectric transducer, in accordance with some embodiments of the present invention.

In some embodiments, the ScₓAl₁₋ₓN ferroelectric transducer comprises a substrate 101, a first electrode 102, a composite stack 109, and a second electrode 108. In some embodiments, the first electrode 102 is positioned above the substrate 101. The substrate 101 may be a silicon layer. In some embodiments, the substrate 101 includes, in part, a Bragg mirror on single crystal silicon layer. In some embodiments, the first electrode 102 may include a Molybdenum (Mo) layer. Alternatively, in some embodiments, the first electrode 102 may include platinum (Pt), gold (Au), silver (Ag), copper (Cu), or aluminum (Al), etc. The first electrode 102 may act as a bottom electrode. In some embodiments, the composite stack 109 comprises a number of alternately stacked ferroelectric layer 104 and transition-metal nitride layer 106. In some embodiments, each transition-metal nitride layer is positioned above a corresponding ferroelectric layer. In some embodiments, there is no transition-metal nitride layer above the topmost ferroelectric layer in the composite stack. In some embodiments, the ferroelectric layer 104 comprises Scandium-doped Aluminum Nitride (ScₓAl₁₋ₓN) films, in which 0<x<1. The ScₓAl₁₋ₓN becomes ferroelectric when Sc-content (e.g., x) exceeds 27%. In some embodiments, the ferroelectric layer 104 comprises ScₓAl₁₋ₓN where x is at least 0.27. In some embodiments, the transition-metal nitride comprises titanium nitride. Alternatively, in some embodiments, the transition-metal nitride comprises tantalum nitride. In some embodiments, the ferroelectric layer 104 has a thickness in the range of about a few nanometers (nm) to about hundreds of nanometers. In some embodiments, the ferroelectric layer 104 has a thickness in the range of about 10 nanometers to about 100 nanometers. In some embodiments, the transition-metal nitride layer 106 has a thickness in the range of about 5 nanometers to about 20 nanometers. In some embodiments, the second electrode 108 is positioned above the composite stack 109. In some embodiments, the second electrode 108 may comprise a Molybdenum (Mo) layer. Alternatively, in some embodiments, the second electrode 108 may comprise platinum (Pt), gold (Au), silver (Ag), copper (Cu), or aluminum (Al), etc. The second electrode 108 may act as a top electrode. In some embodiments, the bottom electrode may act as a grounding electrode, and the top electrode may be coupled to radio frequency (RF) acoustic excitation to the transducer.

In some embodiments, the transducer is formed by successive layering of nanometer-thin ScₓAl₁₋ₓN films and ultra-thin transition-metal nitrides films. In some embodiments, the transition-metal nitrides films may include titanium nitride (TiN) or tantalum nitride (TaN) layers. In some embodiments, film deposition is followed by exposing the stack of films to a rapid thermal annealing (RTA) process at near 900 degree celsius (° C.) to promote formation of ferroelectric crystallinity. In some embodiments, the transducer stack is supported by a substrate like a single crystal silicon wafer. In some embodiments, to acquire a good acoustic resonator's quality factor (Q) of the ScₓAl₁₋ₓN films, the transducer is built on a highly reflective surface, for example, a Bragg mirror fabricated on the substrate. A Bragg mirror is a structure formed of multiple layers made of alternating materials which have different refractive indexes or formed of a dielectric material having periodic variation of some characteristic (such as thickness), resulting in periodic variation in the effective refractive index in the reflective mirror. Each boundary of such alternating material layers causes a partial reflection of the waves in the media. The many reflections combine and form constructive interference.

In some embodiments, each ScₓAl₁₋ₓN film layer in the composite stack is encapsulated by forming capping electrodes with large coefficient of thermal expansion (CTE). In some embodiments, the large coefficient of thermal expansion of the capping electrodes make it possible to use relatively low thermal budget to apply large lateral mechanical stress. In some embodiments, the stress can be induced permanently and at the wafer-level through sputtering at high temperature and low pressures. Alternatively, in some embodiments, the stress can be induced through post-deposition annealing. In some embodiments, the capping electrodes with large CTE comprise transition-metal nitrides layers. In some embodiments, the transition-metal nitride layers comprise titanium nitride (TiN) layers. Alternatively, in some embodiments, the transition-metal nitride layers comprise tantalum nitride (TaN) films. The large coefficient of thermal expansion (CTE) of TiN or TaN films can induce high lateral stress in the composite stack with relatively low thermal budget. In some embodiments, the TiN or TaN films have small lattice mismatch with ScₓAl₁₋ₓN to reduce the disruption in film texture across the composite stack.

FIG. 1b illustrates a schematic cross-sectional view of an exemplary ScₓAl₁₋ₓN ferroelectric transducer, according to some embodiments of the current disclosure.

Referring to FIG. 1b, the ScₓAl₁₋ₓN ferroelectric transducer 100 comprises a substrate 110 as the transducer's carrier. Substrate 110 can be a glass substrate, a quartz substrate, or a semiconductor such as a single crystal silicon wafer. In some embodiments, the substrate 110 is covered with a high-reflective coating 115 like a Bragg mirror. In some embodiments, a first electrode 122 is deposited over the Bragg mirror 115. In some embodiments, the first electrode 122 comprises molybdenum (Mo). Alternatively, in some embodiments, the first electrode 122 may comprise platinum (Pt), gold (Au), silver (Ag), copper (Cu), or aluminum (Al), etc. In some embodiments, the first electrode 122 serves as the ground electrode. In some embodiments, a first layer of ScₓAl₁₋ₓN film 131 is deposited on a first seed layer 161. The first seed layer 161 is grown on the first electrode 122. The first layer of ScₓAl₁₋ₓN film 131 is deposited on the first seed layer 161 by applying one of the film deposition techniques such as the molecular beam epitaxy (MBE), atomic layer deposition (ALD), reactive magnetron sputtering, or physical vapor deposition (PVD). In some embodiments, the first seed layer 161 comprises a thin layer of aluminum nitrite (AlN) grown on the first electrode 122 for better adhesion of the ScₓAl₁₋ₓN film 131.

In some embodiments, a first thin transition-metal nitride layer 151 is deposited on the first ScₓAl₁₋ₓN film 131. In some embodiments, the first transition-metal nitride layer 151 comprises a TiN film. Alternatively, in some embodiments, the first transition-metal nitride layer 151 comprises a TaN film. In some embodiments, the first transition-metal nitride layer 151 can be deposited by applying one of the advanced film deposition techniques, such as the molecular beam epitaxy (MBE), atomic layer deposition (ALD), reactive magnetron sputtering, or physical vapor deposition (PVD).

In some embodiments, a second ScₓAl₁₋ₓN film layer 132 is deposited on a second seed layer 162, grown on the first transition-metal nitride layer 151, by applying one of the film deposition techniques such as reactive magnetron sputtering, MBE, ALD, or PVD. In some embodiments, the second seed layer 162 comprises a thin layer of aluminum nitrite (AlN) grown on the first transition-metal nitride layer 151 for better adhesion of the second ScₓAl₁₋ₓN film layer 132.

In some embodiments, a second thin transition-metal nitride layer 152 is deposited on the second ScₓAl₁₋ₓN film 132. In some embodiments, the second transition-metal nitride layer 152 comprises a TiN film. Alternatively, in some embodiments, the second transition-metal nitride layer 152 comprises a TaN film. In some embodiments, the second transition-metal nitride layer 152 can be deposited by applying one of the film deposition techniques such as reactive magnetron sputtering, MBE, ALD, or PVD. In some embodiments, the film widths of the second ScₓAl₁₋ₓN film 132 and the second transition-metal nitride layer 152 are smaller than those of the first ScₓAl₁₋ₓN film 131 and the first transition-metal nitride layer 151 as shown in the cross-sectional view in FIG. 1b to allow room for applying a polarization voltage 141 on the surface of first transition-metal nitride layer 151.

In some embodiments, a third layer of ScₓAl₁₋ₓN film 133 is deposited on a third seed layer 163 grown on the second transition-metal nitride layer 152. In some embodiments, the deposition of the third ScₓAl₁₋ₓN film layer can be performed by applying one of the film deposition techniques such as MBE, ALD, reactive magnetron sputtering, or PVD. In some embodiments, the third seed layer 163 comprises a thin layer of aluminum nitrite (AlN) and is grown on the second transition-metal nitride layer 152 for better adhesion to the third ScₓAl₁₋ₓN film layer 133.

In some embodiments, a third thin transition-metal nitride layer 153 is deposited on the third ScₓAl₁₋ₓN film layer 133. The third transition-metal nitride layer 153 can be deposited by applying one of the advanced film deposition techniques such as reactive magnetron sputtering, MBE, ALD, or PVD. In some embodiments, the third transition-metal nitride layer 153 comprises a TiN film. Alternatively, in some embodiments, the third transition-metal nitride layer 153 comprises a TaN film. In some embodiments, the film widths of the third ScₓAl₁₋ₓN film 133 and the third transition-metal nitride layer 153 are smaller than those of the second ScₓAl₁₋ₓN film 132 and the second transition-metal nitride layer 152 as shown in the cross-sectional view in FIG. 1b to allow room for applying a polarization voltage 142 on the surface of the second transition-metal nitride film 152.

Referring to FIG. 1b, in some embodiments, a fourth layer of ScₓAl₁₋ₓN film 134 is deposited, on a fourth seed layer 164 grown on the third transition-metal nitride 153, by applying one of the film deposition techniques such as MBE, ALD, reactive magnetron sputtering, or PVD. In some embodiments, the fourth seed layer 164 may be a thin layer of aluminum nitrite (AlN) grown on the third transition-metal nitride layer 153 for better adhesion of the fourth ScₓAl₁₋ₓN film 134. In some embodiments, the fourth ScₓAl₁₋ₓN film layer can be deposited by applying one of the film deposition techniques such as MBE, ALD, reactive magnetron sputtering, or PVD. In some embodiments, the fourth seed layer 164 comprises a thin layer of aluminum nitrite (AlN).

In the example of FIG. 1b, only four ScₓAl₁₋ₓN films are shown. However, the number of ScₓAl₁₋ₓN films is not limited to four layers.

In some embodiments, the top ScₓAl₁₋ₓN film may not be covered by a transition-metal nitride layer. In some embodiments, a second electrode 121 is deposited on the top ScₓAl₁₋ₓN film. For example, in FIG. 1b, the second electrode 121 is deposited on the fourth ScₓAl₁₋ₓN film 134. In some embodiments, the second electrode 121 comprises molybdenum (Mo). Alternatively, in some embodiments, the second electrode 121 may comprise platinum (Pt), gold (Au), silver (Ag), copper (Cu), or aluminum (Al), etc. In some embodiments, the second electrode 121 applies an electric field at an oscillating acoustic frequency to generate acoustic waves in the multiple layered transducer. In some embodiments, each of the first and second molybdenum electrodes has a thickness in the range of 20 nm to 200 nm and is deposited by ALD, MBE, PVD or reactive magnetron sputtering.

In some embodiments, the film width of the fourth ScₓAl₁₋ₓN film 134 is smaller than those of the third ScₓAl₁₋ₓN film 133 and the third transition-metal nitride layer 153, as shown in the cross-sectional view in FIG. 1b to allow room for applying a polarization voltage 143 on the surface of third transition-metal nitride film 153.

The transducer structure 100 in FIG. 1b has a pyramid shape, and each layer of the ScₓAl₁₋ₓN films becomes narrower and thinner than the ScₓAl₁₋ₓN film below it. However, FIG. 1b shows an exemplary case, not necessarily true for other transducers.

The layered architecture substantially increases the stress in each of the films. With the inherent stress, polarization switching is enabled at much lower threshold voltages than a single layer ScₓAl₁₋ₓN transducer device. Furthermore, each of the transition-metal nitrides films sandwiched between two ScₓAl₁₋ₓN films provides electrical access to each ScₓAl₁₋ₓN layer, so DC electric field can be applied to the ScₓAl₁₋ₓN film directly in a parallel manner. Hence, ferroelectric switching of the whole ScₓAl₁₋ₓN film turns on much faster. Thus, the described structure overcomes the aforementioned high threshold coercive field existing in the ScₓAl₁₋ₓN film during polarization switching.

This structure also allows external voltage access for each ScₓAl₁₋ₓN film in parallel which reduces switching time.

In addition, the disclosed ferroelectric ScₓAl₁₋ₓN transducer does not require excessive Sc doping concentrations, therefore it enables ferroelectric switching with relatively low DC voltages available on integrated circuit chips. In this approach, the required energy to surpass the transition barrier from hexagonal to layered-hexagonal morphology, for enhancement of ferroelectric behavior, is accommodated through lateral mechanical stress which is mediated during the deposition of the ScₓAl₁₋ₓN films. This stress is achieved through successive layering of ScₓAl₁₋ₓN films with ultra-thin transition-metal nitrides to enhance residual stress.

Experimental preliminary samples have been fabricated to demonstrate feasibility. For example, highly textured ScₓAl₁₋ₓN films which have thicknesses from 20 nm to 100 nm and desirable Sc concentration from 30% to 45% are deposited using a dual-target reactive co-sputtering system with extended control over processing parameters. As the result, a composite stack was created by successive layering of ScₓAl₁₋ₓN (20 nm to 100 nm thick) with crystalline transition-metal nitride films (5 nm to 20 nm thick) to realize a transducer which has a total 500 nm-1μm thickness. The breaking of structural homogeneity of ScₓAl₁₋ₓN through disruptive layering, along with the large coefficient of thermal expansion of transition-metal nitrides, such as titanium nitride (TiN) and tantalum nitride (TaN), enables stress-mediation of the ScₓAl₁₋ₓN films through rapid thermal annealing (RTA) at a low thermal budget allowed by post-CMOS integration requirements.

Furthermore, the above described transducer enables independent access to each constituent ScₓAl₁₋ₓN layer in the film stack. Therefore, low voltages (<10V) can realize polarization switching of each ScₓAl₁₋ₓN layer and several layers can be switched on/off in parallel mode. The switching time of the transducer will be significantly reduced.

The engineering of ferroelectric properties in the embodiments is enabled through successive layering of ScₓAl₁₋ₓN with transition-metal nitride films (i.e. TiN and TaN) and post-deposition annealing of the stack. Layering the film stack is like dividing a thick ScₓAl₁₋ₓN layer into 20-100 nm constituents that are encapsulated by capping transition-metal nitride electrodes which has large coefficient of thermal expansion (CTE) mismatch. This structure enables application of large lateral mechanical stress with relatively low thermal budget. Such stress can be induced permanently and at the wafer-level, through sputtering at high temperatures and low pressures or by post-deposition annealing.

Besides, independent electrical access to 20-100 nm ScₓAl₁₋ₓN films through interlayer electrodes enables simultaneous polarization switching within a significantly smaller time, compared to a thick single-layer ScₓAl₁₋ₓN film. The choice of TiN/TaN films is made because of 1) their small lattice mismatch with ScₓAl₁₋ₓN films to reduce the disruption in film texture across all layers in the stack, and 2) their large CTE, which is required for stress engineering at a low thermal-budget.

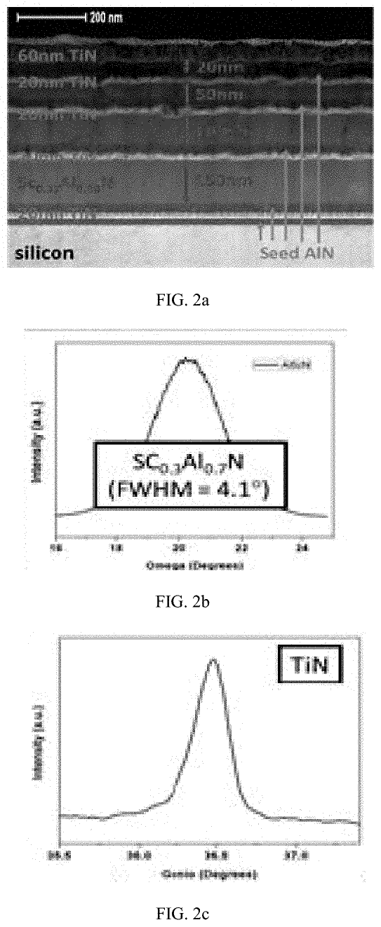

FIG. 2a shows a cross-sectional image from a transmission electron microscopy (XTEM) measurement of a proof-of-concept preliminary stress-mediated Sc_{0.32}Al_{0.68}N—TiN transducer sample. In the sample, a stack of ScₓAl₁₋ₓN/TiN is created through reactive magnetron sputtering technique. A number of TiN layers with a thickness about 20 nanometers are embedded within the ScₓAl₁₋ₓN films.

FIG. 2b shows the X-ray diffraction (XRD) data across the Sc_{0.32}Al_{0.68}N peak and FIG. 2c shows the XRD data across the TiN peak, from the fabricated sample shown in FIG. 2a. The x-ray diffraction measurements highlight the high quality of ScₓAl₁₋ₓN and TiN film crystallinity despite the nonhomogeneous layering.

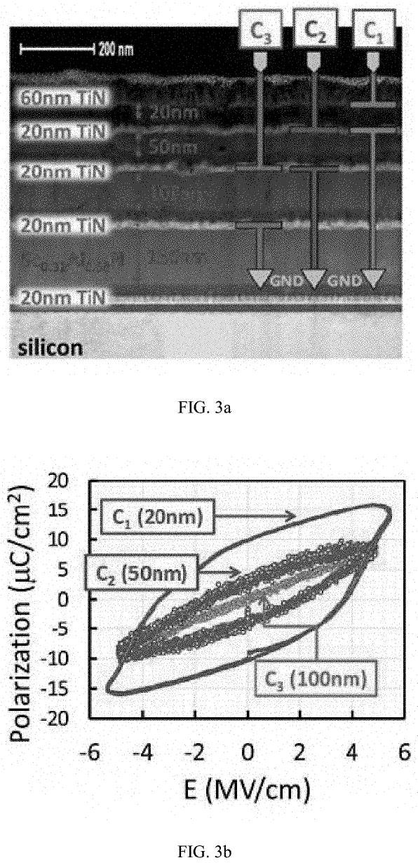

FIG. 3a demonstrates the cross-sectional image from a transmission electron microscopy (XTEM) measurement of the transducer stack of Sc_{0.32}Al_{0.68}N films. Each film layer is made at a different thickness of 150 nm, 100 nm, 50 nm and 20 nm from bottom to top. The stack went through an RTA at 900° C. for 30 seconds. Most TiN layers are deposited at about 20 nanometers except the topmost in FIG. 3a. Note in the sample in FIGS. 2a and 3a, there are no Bragg mirror and molybdenum electrodes fabricated as described in FIG. 1a and FIG. 1b. In FIGS. 3a and 3b, C₁, C₂ and C₃ represent three interlayer film thickness.

FIG. 3b shows measured loops of polarization versus electric field (P-E) of different Sc_{0.32}Al_{0.68}N film layers with different thickness within the transducer stack after an RTA, in accordance with some embodiments. The thicknesses of various Sc_{0.32}Al_{0.68}N film layers are about 20 nm, 50 nm, and 100 nm. The RTA is at 900° C. for 30 seconds.

As shown in FIG. 3b, the ferroelectric behavior is evident in the 20 nm thick (C₁) and 50 nm thick (C₂) Sc_{0.32}Al_{0.68}N films, which can be attributed to the effect of lateral mechanical stress enhanced by the TiN interlayers. However, such stress is not sufficient for the 100 nm layer in this example.

The measured P-E loops of different ScₓAl₁₋ₓN layers within the stack highlight the increased polarization and coercive field (i.e. enhanced ferroelectricity) at lower ScₓAl₁₋ₓN film thicknesses where the stress is larger.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

1. A ferroelectric transducer comprising:
a substrate;
a first electrode positioned above the substrate;
a composite stack positioned above the first electrode, the composite stack comprising one or more alternate layers of a ferroelectric layer and a transition-metal nitride layer; and
a second electrode positioned above the composite stack,
wherein the ferroelectric layer comprises a scandium-doped aluminum nitride layer (ScₓAl₁₋ₓN), and wherein 0<x<1.

2. The ferroelectric transducer of claim 1, wherein each ferroelectric layer has a thickness ranging from about 10 nm to about 100 nm.

3. The ferroelectric transducer of claim 1, wherein 0.27<x<0.45.

4. The ferroelectric transducer of claim 3, wherein the substrate comprises a Bragg mirror on single crystal silicon.

5. The ferroelectric transducer of claim 1, wherein the transition-metal nitride layer comprises titanium nitride (TiN) or tantalum nitride (TaN).

6. The ferroelectric transducer of claim 1, wherein each of the transition-metal nitride layers is coupled to an external switching voltage for switching a polarization of a corresponding ScₓAl₁₋ₓN layer.

7. The ferroelectric transducer of claim 6, wherein the external switching voltage of each transition-metal nitride layer is independently controlled from each other.

8. The ferroelectric transducer of claim 1, wherein the first and second electrodes comprise at least one of molybdenum, platinum, gold, silver, copper, or aluminum.

9. The ferroelectric transducer of claim 1, wherein the transition-metal nitride layer is positioned above a corresponding ferroelectric layer except the topmost ferroelectric layer in the composite stack.

10. A method of fabricating a ferroelectric transducer, comprising:
forming a first electrode above a substrate;
forming a composite stack above the first electrode, the composite stack comprising one or more alternate layers of a ferroelectric layer and a transition-metal nitride layer; and
forming a second electrode above the composite stack,
wherein the ferroelectric layer comprises a scandium-doped aluminum nitride layer (ScₓAl₁₋ₓN), and wherein 0<x<1.

11. The method of claim 10, wherein the transition-metal nitride layer is positioned above a corresponding ferroelectric layer except the topmost ferroelectric layer in the composite stack.

12. The method of claim 10, wherein the ferroelectric layer is formed by applying one of film deposition techniques comprising molecular beam epitaxy (MBE), atomic layer deposition (ALD), reactive magnetron sputtering, or physical vapor deposition (PVD).

13. The method of claim 10, wherein the transition-metal nitride layer comprises titanium nitride (TiN) or tantalum nitride (TaN).

14. The method of claim 10 further comprising forming a seed layer before forming each of the ferroelectric layers.

15. The method of fabricating the ferroelectric transducer of claim 14, wherein the seed layer comprises aluminum nitride (AlN).

16. The method of claim 10, wherein the transition-metal nitride layer is formed by applying one of deposition techniques comprising molecular beam epitaxy (MBE), atomic layer deposition (ALD), reactive magnetron sputtering, or physical vapor deposition (PVD).

17. The method of claim 10 further comprising applying rapid thermal annealing (RTA) to the composite stack at a predetermined temperature.

18. The method of claim 17, wherein the predetermined temperature cannot damage the ferroelectric transducer.

19. The method of claim 10 further comprising forming a Bragg mirror on the substrate and under the first electrode.

20. The method of claim 10, wherein 0.27<x<0.45.
